(19) United States
(12) Patent Application Publication
(10) Pub. No.: US 2026/0031837 A1
(43) Pub. Date: Jan. 29, 2026

(54) DECODER FOR VITERBI DECODING, OPERATION METHOD AND ELECTRONIC DEVICE

(71) Applicant: SAMSUNG ELECTRONICS CO., LTD., Suwon-si (KR)

(72) Inventors: Eunyoung SEO, Suwon-si (KR); JONGHYUN BAIK, Suwon-si (KR); JUNG WOON LEE, Suwon-si (KR)

(73) Assignee: SAMSUNG ELECTRONICS CO., LTD., Suwon-si (KR)

(21) Appl. No.: 19/235,101

(22) Filed: Jun. 11, 2025

(30) Foreign Application Priority Data
Jul. 24, 2024 (KR) 10-2024-0098076

(51) Int. Cl. H03M 13/41

(52) U.S. Cl. CPC H03M 13/4115

(57) ABSTRACT

A receiver includes a demodulator configured to demodulate a received signal, a despreader configured to, based on a reference chip sequence, perform dispreading on a demodulation signal corresponding to the demodulation of the received signal; and a decoder configured to determine a survivor path for states based on a correlation value corresponding to the despreading, while omitting calculation of a log-likelihood ratio (LLR) for a symbol included in the demodulation signal, and output a decoding signal by tracing back the survivor path.

### CROSS-REFERENCE TO RELATED APPLICATION(S)

This U.S. non-provisional application is based on and claims priority under 35 USC § 119 to Korean Patent Application No. 10-2024-0098076, filed on Jul. 24, 2024, in the Korean Intellectual Property Office, the disclosure of which is herein incorporated by reference in its entirety.

### BACKGROUND

Example embodiments of the disclosure relate to a decoder for Viterbi decoding, an operation method, and an electronic device.

Typically, errors may occur during the transmission of data from a transmission terminal to a receiving terminal. Therefore, error correcting coding may be required to correct such errors. The transmission terminal may encode and transmit data to be transmitted and the receiving terminal may decode the encoded data, resulting in improved reliability of the data. Examples of error correcting coding include block coding, convolutional coding, turbo coding, low-density parity-check (LDPC) coding, or the like.

When convolutional coding is applied, the receiving terminal may decode a received signal using Viterbi decoding. In general, Viterbi decoding is performed based on a bit-wise log-likelihood ratio (LLR).

### SUMMARY

One or more example embodiments of the disclosure provide a decoder for efficient Viterbi decoding, an operation method thereof, and an electronic device for efficient Viterbi decoding.

According to an aspect of an example embodiment, a receiver includes a demodulator configured to demodulate a received signal, a despreader configured to, based on a reference chip sequence, perform dispreading on a demodulation signal corresponding to the demodulation of the received signal; and a decoder configured to determine a survivor path for states based on a correlation value corresponding to the despreading, while omitting calculation of a log-likelihood ratio (LLR) for a symbol included in the demodulation signal, and output a decoding signal by tracing back the survivor path.

According to an aspect of an example embodiment, a method of operating a decoder includes receiving a correlation value corresponding to despreading for a demodulation signal, determining a survivor path for states based on the correlation value, while omitting calculation of a log-likelihood ratio (LLR) for a symbol included in the demodulation signal, and outputting a decoding signal by tracing back the survivor path.

According to an aspect of an example embodiment, an electronic device includes at least one memory configured to store at least one instruction and at least one processor configured to execute the at least one instruction. The at least one processor, by executing the at least one instruction, may be configured to receive a correlation value corresponding to despreading for a demodulation signal, determine a survivor path for states based on the correlation value, while omitting calculation of a log-likelihood ratio (LLR) for a symbol included in the demodulation signal, and output a decoding signal by tracing back the survivor path.

### BRIEF DESCRIPTION OF DRAWINGS

The above and other aspects and features of the disclosure will become more apparent by describing in detail example embodiments thereof with reference to the attached drawings.

FIG. 1 is a block diagram of a transmitter according to one or more example embodiments.

FIG. 2 is a block diagram of a receiver according to one or more example embodiments.

FIG. 3 is a diagram illustrating a concatenated trellis diagram of a Viterbi decoder according to one or more example embodiments.

FIG. 4 is a diagram illustrating a trellis diagram of a Viterbi decoder according to one or more example embodiments.

FIG. 5 is a block diagram of a receiver according to one or more example embodiments.

FIG. 6 is a block diagram of a decoder according to one or more example embodiments.

FIG. 7 is a diagram illustrating a trellis diagram according to one or more example embodiments.

FIG. 8 is a diagram illustrating a decoder according to one or more example embodiments.

FIG. 9 is a diagram illustrating a radix-4 decoder according to one or more example embodiments.

FIG. 10 is a flowchart illustrating a method of operating a decoder according to one or more example embodiments.

FIG. 11 is a flowchart illustrating a method of determining a survivor path of a decoder according to one or more example embodiments.

FIG. 12 is a block diagram of a receiver according to one or more example embodiments.

FIG. 13 is a diagram illustrating a wireless communication device according to one or more example embodiments.

FIG. 14 is a block diagram of an electronic device according to one or more example embodiments.

### DETAILED DESCRIPTION

Hereinafter, one or more example embodiments will be described with reference to the accompanying drawings.

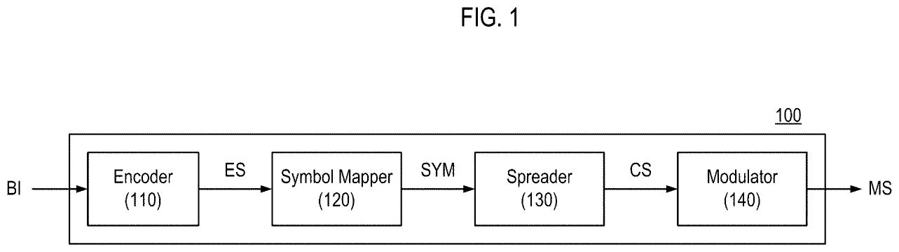

FIG. 1 is a block diagram of a transmitter according to one or more example embodiments.

Referring to FIG. 1, a transmitter 100 according to one or more example embodiments may include an encoder 110, a symbol mapper 120, a spreader 130, and a modulator 140.

The encoder 110 may receive a bit signal and encode the received bit signals to output an encoded signal (or a codeword) ES.

For example, the encoder 110 may be implemented as a convolutional encoder. The encoded signal ES may become a convolutional code. The encoder 110 may be configured to include one or more memories, not illustrated. For example, the one or more memories may be implemented as a shift register. If a number of the one or more memories included in the encoder 110 is 1 (where 1 is a positive integer), then a constraint length is defined as 1+1. As the constraint length increases, more previous bits affect output bits.

The encoder 110 may encode bit information BI based on a polynomial defined based on the above-described one or more memories and an adder. When a size of the bit information BI is defined as m bits and a size of the encoded signal ES is defined as n bits (where m and n are positive integers), a coding rate of the encoder 110 may be defined as n/m.

The symbol mapper 120 may map the encoded signal ES, output from the encoder 110, to a symbol SYM. For example, the symbol mapper 120 may map a plurality of bits, included in the encoded signal ES, to a single symbol SYM for each specific bit unit.

The spreader 130 maps each of the plurality of symbols SYM, output from the symbol mapper 120, to a chip sequence (or a chip value) CS. For example, the spreader 130 may spread each symbol SYM to the chip sequence CS by multiplying each symbol SYM by a chip code. The chip sequence CS may be output through the spreader 130. A spreading operation of the spreader 130 may be defined as a direct sequence spread spectrum (DSSS). Due to the spreading operation, the symbol SYM may have a wider bandwidth. The wider the bandwidth is, the higher the likelihood that the symbol SYM is decoded into original data is.

By spreading the symbol SYM into a chip, the symbol SYM may have a wider bandwidth, and a security and a robustness of the signal may be improved.

The modulator 140 may modulate the chip sequence CS to output a modulated signal MS. For example, the modulator 140 may modulate the chip sequence CS through various modulation schemes such as amplitude shift keying (ASK), frequency shift keying (FSK), phase shift keying (PSK), or quadrature amplitude modulation (QAM). The modulator 140 according to one or more example embodiments may perform modulation based on offset-quadrature phase shift keying (O-QPSK).

The modulated signal MS may be output through the modulator 140. The modulated signal MS may be transmitted to a receiver through a channel.

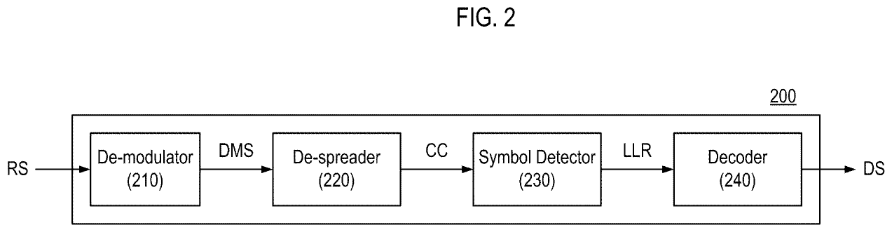

FIG. 2 is a block diagram of a receiver according to one or more example embodiments.

Referring to FIG. 2, a receiver 200 according to one or more example embodiments may include a demodulator 210, a despreader 220, a symbol detector 230, and a decoder 240.

The demodulator 210 may demodulate a receive signal RS received through the receiver 200. A demodulated signal DMS, demodulated through the demodulator 210, may be a signal spread by the transmitter (for example, 100 in FIG. 1). The despreader 220 may despread the demodulated signal DMS using a chip sequence. A correlation value CC may be output by the despreading.

The symbol detector 230 may determine whether a bit of the received signal is 0 or 1, based on the correlation value CC output through the despreader 220. When a soft decision-based receiver is provided, the symbol detector 230 may calculate and output a log-likelihood ratio (LLR). Each bit of the receive signal RS may be softly represented, and the symbol detector 230 may calculate the likelihood that a soft value of each bit represents 0 or 1 as an LLR.

The LLR may be calculated bit-wise. For example, when a single symbol is mapped to 4 bits, four LLRs may be calculated for each symbol.

The decoder 240 may decode the receive signal RS based on the LLR to output a decoding signal DS corresponding to bit information of an original signal, from the receive signal RS. When the encoding of the transmitter is performed based on a binary convolutional code, the decoder 240 may be implemented as a Viterbi decoder.

The receiver 200 may process the receive signal RS sequentially through the demodulator 210, the despreader 220, and the symbol detector 230, and the decoder 240 may decode a processed version of the receive signal RS. For example, performance of the decoder 240 may be limited by performance of blocks disposed at a front end of the decoder 240 (for example, the demodulator 210, the despreader 220, and the symbol detector 230). For example, the symbol detector 230 outputs an LLR, the likelihood that each bit is 0 or 1 from the soft value. When the symbol detector 230 makes an incorrect determination, the decoder 240 may be subsequently impacted.

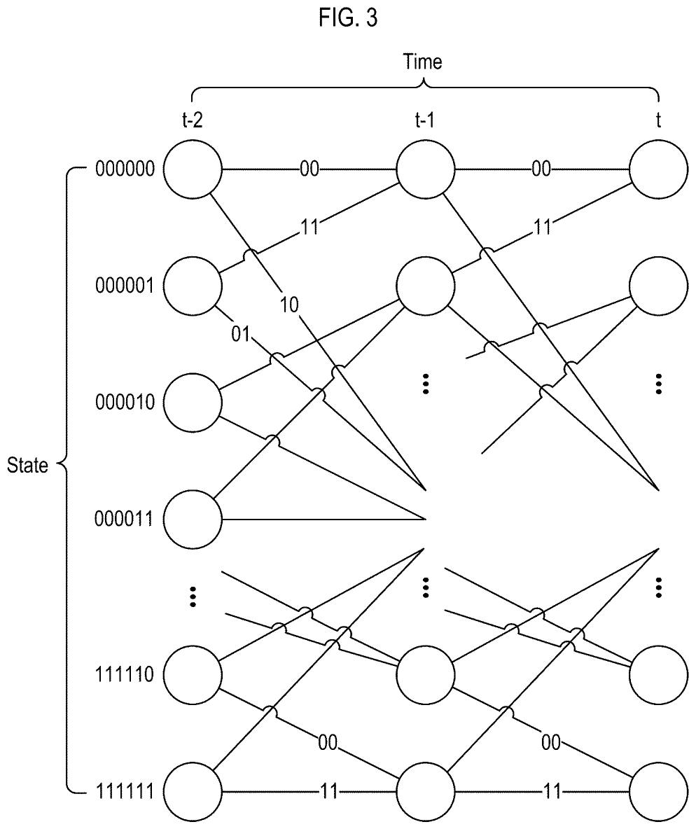

FIG. 3 is a diagram illustrating a concatenated trellis diagram of a Viterbi decoder according to one or more example embodiments.

Referring to FIG. 3, a trellis diagram is a graph illustrating possible states at each time and possible transitions between the possible states. A received signal is an encoded version of an original signal transmitted by a transmitter, and the original signal may be decoded using a trellis diagram.

A state may be defined based on a combination of binary bits stored in one or more memories included in an encoder of the transmitter. For example, there may be 21 states, wherein 1 denotes a number of memories. For example, when the number of memories 1 is 2, there may be 4 states. FIG. 3 corresponds to an example in which 1=6. Therefore, the state may be represented as a combination of 6 bits. Hereinafter, a number of states that is 21 may also be defined as k.

A transition between states may occur according to new bit information input to the decoder. A number of transitions may vary depending on an input bit value. For example, if a Radix-2 decoder processes one bit of input to produce two bits of output, then two transitions may occur in a single state. Also, if n bits of input (where n is greater than or equal to 2) is provided, then 2″ transitions may be defined. Hereinafter, a number of the transitions may be defined as j.

A single transition may be represented as a branch in the trellis diagram. A branch may represent an encoded output bit generated when transitioning from a current state (or current time) to a next state (or next time). If a coding rate is 2, then two bits of output may be encoded for one bit of input, as illustrated in FIG. 3. Each branch represents two bits of output when a transition occurs.

As illustrated in the drawing, a trellis diagram may be concatenated. If a Radix-2 decoder outputs two bits of output, then the trellis diagram of FIG. 3 having a coding rate of 2 may be concatenated. In practice, the trellis diagram represents 4 bits of output.

For example, the illustrated trellis diagram represents transitions between states at times t−2, t−1, and t. Two transitions, which may be defined for a state “00000” at time t−1, may be transitions for states “000000” and “000001” and output bits corresponding to these states may be “00” and “11,” respectively. Two transitions may also be defined for the state “000000” at time t. However, when extended to time t−2, four transitions may be defined for the state “000000” at time t.

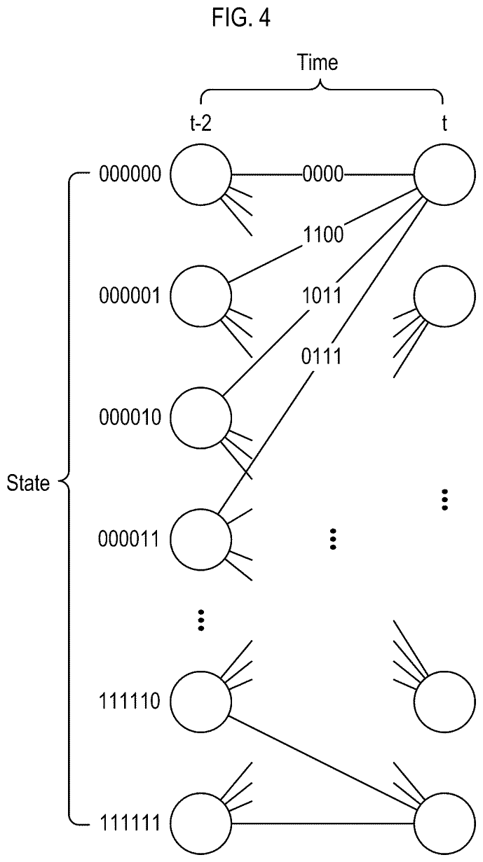

FIG. 4 is a diagram illustrating a trellis diagram of a Viterbi decoder according to one or more example embodiments.

Referring to FIG. 4, if a Radix-4 decoder decodes 4 output bits, then four transitions may occur in a single state. Also, an arbitrary state at a current time t may have four candidate branches corresponding to four previous states. For example, a state “000000” at time t may have four branches connected to states “000000,” “000001,” “000010,” and “000011” at previous time t−2.

A number of branches or candidates that an arbitrary state in the above-described trellis diagram may have may vary depending on the configuration of a decoder.

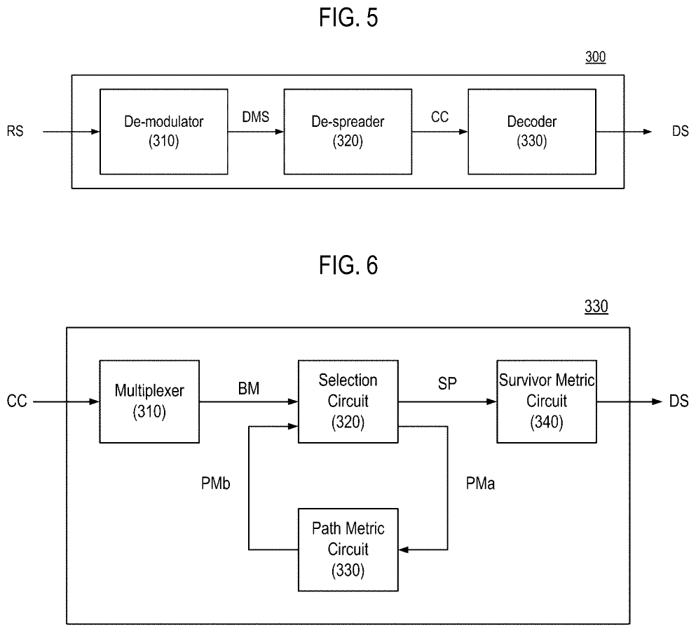

FIG. 5 is a block diagram of a receiver according to one or more example embodiments.

Referring to FIG. 5, a receiver 300 according to one or more example embodiments may include a demodulator 310, a despreader 320, and a decoder 330.

The demodulator 310 may be configured to receive a receive signal RS and demodulate the receive signal RS. For example, the receive signal RS may be received through a channel from a transmitter according to the above-described one or more embodiments (for example, 100 in FIG. 1), and may be a signal that has been encoded, symbol-mapped, spread, and/or modulated through the transmitter. For example, the receive signal RS may be a signal that has been O-QPSK modulated in the transmitter.

A demodulation signal DMS may be output through the demodulator 310. The demodulation signal DMS may be a spread signal corresponding to a symbol.

The despreader 320 may be configured to despread the demodulation signal DMS corresponding to demodulation based on a reference chip sequence. The reference chip sequence may be the same chip sequence used for spreading in the transmitter, and may be generated or prestored in the receiver 300.

The despreader 320 may perform despreading by correlating the demodulation signal DMS with the reference chip sequence. The correlation may calculate a correlation value CC indicating a degree of correlation between the demodulation signal DMS and the reference chip sequence. The higher the correlation is, the more accurate the decoding is. Therefore, the correlation may be considered as indicating the reliability of each symbol. When a received symbol has a high correlation with a specific reference chip sequence, the symbol is considered to be likely to represent bit information mapped to the reference chip sequence.

The correlation value CC may be defined for each bit combination of the symbol included in the demodulation signal DMS. For example, when bits mapped to a symbol in the transmitter are 4 bits, the correlation value CC may be defined for each of 16 bit combinations for 4 bits.

The decoder 330 may perform decoding based on the correlation value CC corresponding to the despreading performed by the despreader 320. In one or more example embodiments, the decoder 330 may directly regard the correlation value CC as a branch metric between states. For example, the decoder 330 may determine a survivor path for states based on the correlation value CC being used as a branch metric.

As described above in FIG. 3, branches that an arbitrary state (for example, a first state) at an arbitrary time may have for a state (for example, a second state) at a previous time may correspond to an output bit (for example, an encoded signal) that may be encoded while changing a memory combination of the encoder of the transmitter from the second state to the first state. The branch metric defined for each branch may represent a degree of matching, a cost, and/or a distance between an output bit represented by a single branch and the receive signal RS. A smaller branch metric may indicate that the distance between the output bit and the receive signal RS is smaller, and/or a degree of matching between the output bit and the receive signal RS is higher.

Thus, the decoder 330 according to one or more example embodiments may calculate a path metric and determine a survivor path by directly using the correlation value CC, which represents a correlation of the symbol, as a branch metric.

As described above, the correlation value CC may be defined for a bit combination of a symbol, and a single branch representing one of the bit combinations of the symbol may correspond to a single correlation value CC.

The decoder 330 may trace back the determined survivor path to output a decoding signal. The decoder 330 may trace back the survivor path from a last state to a first state and restore bit information BI corresponding to the branches included in the survivor path through a tracing process.

The decoder 330 according to the above-described one or more embodiments may directly use the correlation value CC, representing the reliability of the symbol, as a branch metric without calculating a branch metric. As a result, the decoder 330 according to one or more example embodiments may decode the receive signal RS without hardware elements for calculating the branch metric, and may not be affected by the performance of hardware elements for calculating the branch metric.

FIG. 6 is a block diagram of a decoder according to one or more example embodiments.

Referring to FIG. 6, a decoder 330 according to one or more example embodiments may include a multiplexer 310, a selection circuit 320, a path metric circuit 330, and a survivor metric circuit 340.

The multiplexer 310 may be configured to select as many correlation values CC as the number of branches that an arbitrary state may have from among a plurality of correlation values CC corresponding to bit combinations. For example, the multiplexer 310 may receive a plurality of correlation values CC (for example, correlation values CC corresponding to bit combinations for a single symbol) and select as many correlation values CC as the number of branches that an arbitrary state has from among the plurality of correlation values CC. For example, the multiplexer 310 may select correlation values CC corresponding to an output bit corresponding to branches.

In one or more example embodiments, the multiplexer 310 may receive a selection signal, not illustrated, for selecting the correlation value CC. The selection signal, not illustrated, may be configured to select a correlation value CC corresponding to branches that an arbitrary state has.

The correlation value, selected through the multiplexer 310 may be regarded as a branch metric BM. For example, a selected correlation value as many as the number of branches may be defined as a branch metric BM for an arbitrary state. The selected correlation value may be transmitted to the selection circuit 320, as a branch metric BM.

The selection circuit 320 may be configured to calculate a path metric based on addition and comparison operations and select a survivor path SP defined as a path having a minimum value, among path metrics.

For example, the selection circuit 320 may add a path metric for a plurality of previous states of an arbitrary state and the branch metric BM for a plurality of previous transitions of the arbitrary state. Through the addition, a plurality of summation results may be calculated for the arbitrary state. The selection circuit 320 may determine a minimum value, among the plurality of summation results, as a path metric of the current state.

For example, the selection circuit 320 may update the path metric based on the following equation 1.

$$PM = min ( {PM}_{1} \cdot ( ta ) + {BM}_{1} ( t b ) , P {M}_{2} \cdot ( ta ) + {BM}_{2} ( t b ) , ( … ) , {PM}_{N} \cdot ( ta ) + {BM}_{M} ( t b ) ) , \qquad Equation 1$$

where PM is an updated path metric, PMN′ is a path metric updated or calculated for an N'th previous state (where N′ is a positive integer), and BMM is a branch metric BM for an Mth bit combination of a symbol (where M is a positive integer). BMM is a correlation value CC, which is an output value of a despreader according to the above-described one or more embodiments (for example, FIG. 5). For example, BMM is a correlation value CC corresponding to an Mth bit combination of the symbol. tb is the current time, and ta is a time before tb.

In the update operation, the selection circuit 320 may store an updated path metric PMa in the path metric circuit 330. Also, the selection circuit 320 may retrieve the path metric PMb for a previous state to be used to update a path metric at a current stage from the path metric circuit 330.

The selection circuit 320 may perform calculation and update of the path metric for all states defined in a trellis diagram. The selection circuit 320 may determine a survivor path SP based on a path metric having a minimum value, among the path metrics of the current state. For example, the selection circuit 320 may determine the survivor path SP based on a finally updated path metric, indicating a minimum value among the path metrics of the current state. For example, the selection circuit 320 may select the path having the minimum path metrics at the current time as the survivor path SP.

The selection circuit 320 may store the determined survivor path SP in the survivor metric circuit 340.

The path metric circuit 330 may be configured to store the path metric calculated and updated from the selection circuit 320.

The survivor metric circuit 340 may be configured to store the survivor path SP selected from the selection circuit 320 and output a decoding signal DS through traceback along the stored survivor path SP. For example, when the path metric is accumulated enough to be reliable for the input data (for example, when the survivor path SP is determined), the survivor metric circuit 340 may estimate a transmit signal through traceback. In the traceback process, a sequence of output bits corresponding to each branch may be output as the decoding signal DS.

For example, if a cumulative length of data that may be reliably estimated for a survivor path SP is defined as a traceback depth T (where T is a positive integer), then the survivor path SP may be defined as having a bit length equal to the traceback depth T. The survivor metric circuit 340 and the decoder 330 may store the path metric and the survivor path SP for a time period N times the depth (for example, N is 2) for buffering, and the survivor metric circuit 340 may execute traceback from a time NXT. The traceback may be performed by tracing back the path from a time T to 0.

According to the above-described one or more embodiments, the decoder 330 may decode the received signal by using the correlation value CC as the branch metric BM, thereby eliminating a need for a configuration to calculate the branch metric BM. For example, the decoder 330 according to one or more example embodiments may not require LLR calculation for calculating the branch metric BM.

When DSSS with spreading and O-QPSK modulation are employed at a transmitter, the received signal may be represented as a chip-level value. Therefore, it may be difficult to calculate the LLR, a bit-level soft value, which was originally an output unit of the transmitter. The decoder 330 according to one or more example embodiments omits the calculation of the LLR and regards the correlation value CC as the branch metric BM, such that decoding performance may be improved even when DSSS and O-QPSK modulation are employed at the transmitter.

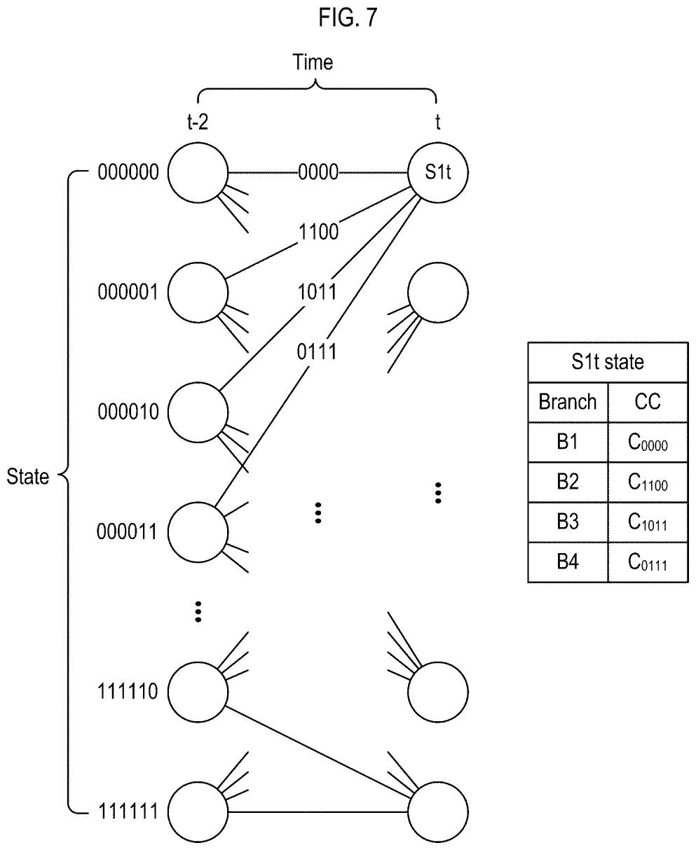

FIG. 7 is a diagram illustrating a trellis diagram according to one or more example embodiments.

Referring to FIG. 7, a decoder according to one or more example embodiments may be implemented as a Radix-4-based decoder. The Radix-4 decoder may use a trellis diagram (for example, FIG. 3) in which two trellis diagrams of a Radix-2 decoder are concatenated. The concatenated trellis diagrams may be represented as illustrated in FIG. 4 and/or FIG. 7.

The Radix-4 decoder may process input bits in units of 2 bits, and an arbitrary state may have 4 branches for a previous time. For example, there are 4 candidates for a previous path that may be estimated from an arbitrary state. Each branch may correspond to an encoded output bit having a size of 4 bits.

A branch metric may be defined for first to fourth branches B1 to B4 that an arbitrary state has. According to one or more example embodiments, the branch metric for each branch may be directly regarded as a correlation value CC.

As illustrated in the drawing, an example is provided in which an encoding signal corresponding to the first branch B1 transitioning from a state “000000” to a state “000000” is “0000,” an encoding signal corresponding to the second branch B2 transitioning from a state “000001” to a state “000000” is “1100,” an encoding signal corresponding to the third branch B3 transitioning from a state “000010” to a state “000000” is “1011,” and an encoding signal corresponding to the fourth branch B4 transitioning from a state “000011” to a state “000000” is “0111.”

Accordingly, the branch metric for the first branch B1 may be a correlation value (CC) “C0000” calculated for an encoding signal “0000,” the branch metric for the second branch B2 may be a correlation value (CC) “C1100” calculated for an encoding signal “1100,” the branch metric for the third branch B3 may be a correlation value (CC) “C1011” calculated for an encoding signal “1011,” and the branch metric for the fourth branch B4 may be a correlation value (CC) “C0111” calculated for an encoding signal “0111.”

If four previous states (for example, 000000, 000001, 000010, and 000011) at time t−2, which is two time units before the current time t, for an arbitrary state S1t are referred to as A′ to D′, then the decoder according to one or more example embodiments may update a path metric for the arbitrary state S1t based on the following equation 2.

$$PM = min ( {PM}_{A} \cdot ( t - 2 ) + {BM}_{A} ( t ) , {PM}_{B} \cdot ( t - 2 ) + {BM}_{B} ( t ) , P {M}_{C} \cdot ( t - 2 ) + {BM}_{C} ( t ) , P {M}_{D} \cdot ( t - 2 ) + {BM}_{D} ( t ) ) , \qquad Equation 2$$

where PM is an updated path metric for the arbitrary state S1t at the current time t, PM_{A′}(t−2), PM_{B′}(t−2), PM_{C′}(t−2), and PM_{D′}(t−2) are path metrics calculated for the previous states, and BM_{A}(t), BM_{B}(t), BM_{C}(t), and BM_{D}(t) are the branch metrics (for example, a correlation value CC) for the first to fourth branches.

The decoder may determine a path corresponding to a minimum value, among the calculated path metrics, as a survivor path.

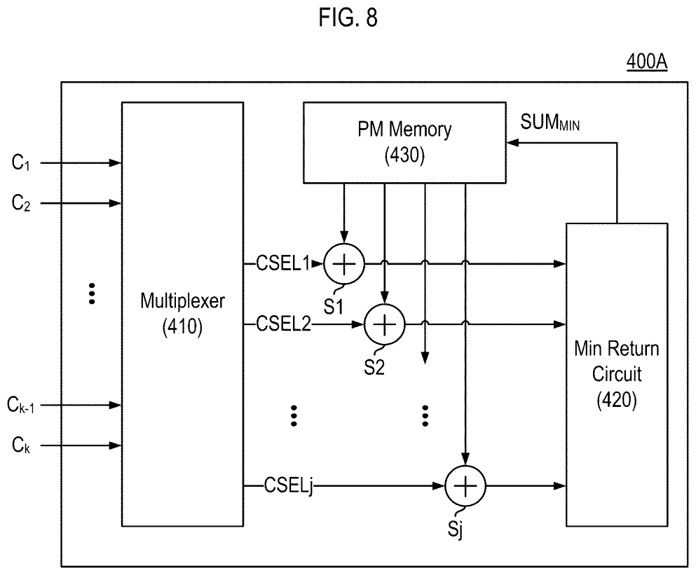

FIG. 8 is a diagram illustrating a decoder according to one or more example embodiments.

Referring to FIG. 8, a decoder 400A according to one or more example embodiments may include a multiplexer 410, a plurality of adders S1 to Sj, a minimum return circuit 420, and a path metric memory 430.

The multiplexer 410 may be configured to receive a plurality of correlation values Co to Ck and select a number of correlated values equal to the number of branches that an arbitrary state, among the plurality of correlated values Co to Ck, may have. The number of branches may be the same as the number of possible transitions from a single state, and the multiplexer 410 may select j correlation values CSEL1 to CSELj.

The multiplexer 410 may output the selected j correlation values CSEL1 to CSELj to the plurality of adders S1 to Sj.

The plurality of adders S1 to Sj may be provided to receive correlation values selected from the multiplexer 410. Each adder of the plurality of adders S1 to Sj receives a corresponding correlation value. Also, the plurality of adders S1 to Sj may respectively receive a plurality of path metrics from the path metric memory 430. Similarly, the number of the path metrics provided from the path metric memory 430 may be j. Each provided path metric may correspond to a correlation value that is to be added by each adder of the plurality of adders S1 to Sj.

For example, when the first adder S1 receives the first selected correlation value CSEL1 and the first selected correlation value CSEL1 is “C0000” corresponding to the first branch of FIG. 7, the path metric provided to the first adder S1 may be a path metric calculated for the first branch. Similarly, if an j-th adder Sj receives a j-th selected correlation value CSELj corresponding to a specific branch, the path metric provided to the j-th adder Sj may be a path metric calculated for the specific branch.

The plurality of adders S1 to Sj may add the received correlation value and path metric and provide a plurality of sum values to the minimum return circuit 420.

The minimum return circuit 420 may be configured to select a path metric representing a minimum value from among the plurality of sum values provided from the plurality of adders S1 to Sj. For example, the minimum return circuit 420 may select a minimum value SUMₘᵢₙ from among sum values, a result of adding the path metric and the correlation value for all branches (or transitions) that may be defined for an arbitrary state, and return the selected minimum value SUMₘᵢₙ.

According to one or more example embodiments, the minimum return circuit 420 may return the minimum value SUMₘᵢₙ based on the above equation 2. The returned minimum value SUMₘᵢₙ may be provided to the path metric memory 430.

The path metric memory 430 may store the provided minimum value SUMₘᵢₙ. Accordingly, the path metric memory 430 may update and store the minimum value SUMₘᵢₙ for all times and all states. For example, path metrics for all times for an arbitrary state may be stored in the path metric memory 430.

The decoder 400A according to the above-described one or more embodiments may decode the received signal, without including a configuration to calculate the branch metric, by using a correlation value as a branch metric.

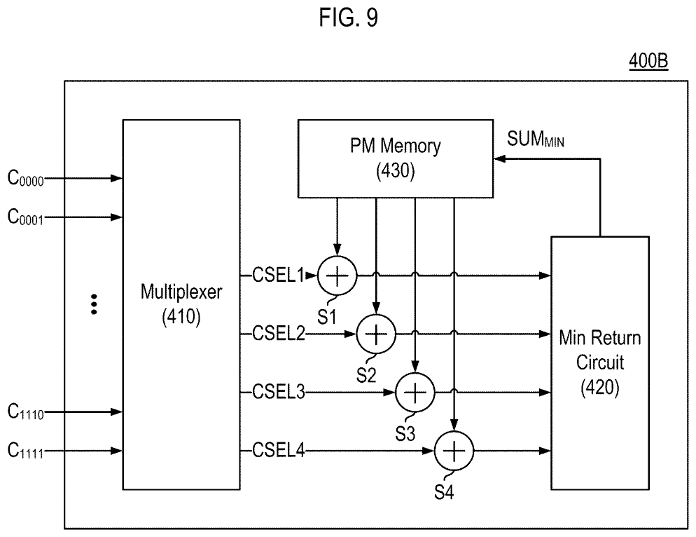

FIG. 9 is a diagram illustrating a radix-4 decoder according to one or more example embodiments.

Referring to FIG. 9, a decoder 400B according to one or more example embodiments may be implemented as a Radix-4 decoder that processes input bits in units of 2 bits and each state having 4 branches. A coding rate of a transmitter may be 2, and an encoded output bit may be 4 bits.

Accordingly, correlation values provided to the multiplexer 410 may correspond to 4 bits of a bit combination, and a total of 16 correlation values C0000 to C1111 may be provided. The multiplexer 410 may be implemented as a 16-to-4 multiplexer to select correlation values corresponding to 4 branches from among the 16 correlation values C0000 to C1111.

The multiplexer 410 may select a first selection correlation value to a fourth selection correlation value CSEL1 to CSEL4 from among the 16 correlation values C0000 to C1111. The first selection correlation value CSEL1 may be provided to a first adder S1, the second selection correlation value CSEL2 may be provided to a second adder S2, the third selection correlation value CSEL3 may be provided to a third adder S3, and the fourth selection correlation value CSEL4 may be provided to a fourth adder S4.

The first to fourth adders S1 to S4 may receive the first selection correlation value to the fourth selection correlation value CSEL1 to CSEL4 from the multiplexer 410 and receive a path metric corresponding to each branch from the path metric memory 430. The first to fourth adders S1 to S4 may add the received correlation values and path metrics, respectively, and provide a sum value to the minimum return circuit 420.

The minimum return circuit 420 may select a single sum value SUMₘᵢₙ representing the minimum value from among the four sum values and provide the selected sum value SUMₘᵢₙ to the path metric memory 430 as an updated path metric.

In the example embodiments of FIGS. 8 and 9, the adder and the minimum return circuit may be implemented to be included in the selection circuit of FIG. 6. Alternatively, the path metric memory may be implemented to be included in the path metric circuit of FIG. 6.

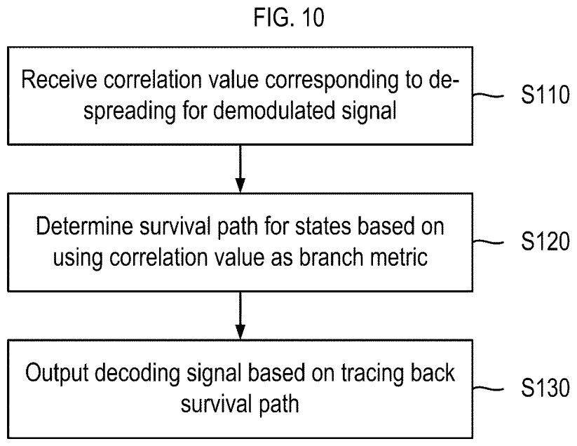

FIG. 10 is a flowchart illustrating a method of operating a decoder according to one or more example embodiments.

Referring to FIG. 10, in operation S10, a decoder according to one or more example embodiments may receive a correlation value corresponding to despreading of a demodulation signal. According to the above-described one or more embodiments, the correlation value may be obtained through demodulation and despreading from a receive signal.

In addition, a decoder may receive a correlation value for each symbol. The correlation value may be defined for each bit combination of the symbol included in the demodulation signal. Accordingly, the decoder may receive as many correlation values as the number of bit combinations of the symbol. For example, when a single symbol is mapped to 4 bits, the decoder may receive 16 correlation values.

In operation S120, the decoder may determine a survivor path for states based on a correlation value being used as a branch metrics between the states. For example, the decoder may regard the received correlation value as a branch metric.

In operation S130, the decoder may output a decoded signal by tracing back the survivor path determined in operation S120. For example, the decoder may restore bit information corresponding to the branches included in the survivor path while tracing back the determined survivor path.

According to the method of operating the decoder according to the above-described one or more embodiments, an operation of calculating the branch metric may be omitted, such that more efficient decoding may be performed.

In one or more example embodiments, the method may further include an operation of selecting as many correlation values as the number of branches that an arbitrary state may have, from among a plurality of correlation values corresponding to bit combinations. The operation of selecting the correlation value may be performed after operation S110 of receiving the correlation value. The number of correlation values may be defined as a branch metric for the arbitrary state.

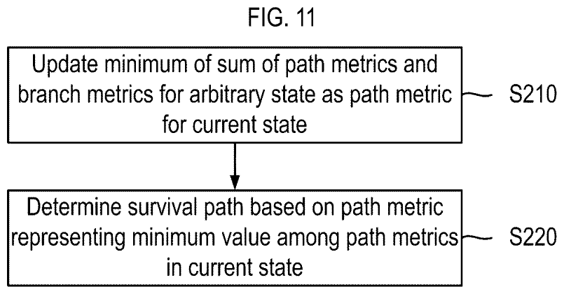

FIG. 11 is a flowchart illustrating a method of determining a survivor path of a decoder according to one or more example embodiments.

Referring to FIG. 11, in operation S210, the decoder may update a path metric of a current state to a minimum value, among the sum of path metrics of a plurality of previous states and branch metrics of the plurality of previous transitions for an arbitrary state. Operation S210 may be iteratively performed for all times and all states in a trellis diagram.

In operation S220, the decoder may determine a survivor path based on a path metric representing the minimum value, among the path metrics of the current state. For example, the decoder may determine a path that may be defined with a minimum cost, as a survivor path, from among the previous states and previous branch candidates defined based on the current state. The survivor path may be considered as corresponding to a signal that is most likely to be an original signal transmitted from a transmitter.

For example, when a binary convolutional code has a coding rate of 2, a single symbol may be mapped to 4 bits. Then, the decoder may determine a most likely path corresponding to 4 bits, as a survivor path, from among the candidate paths.

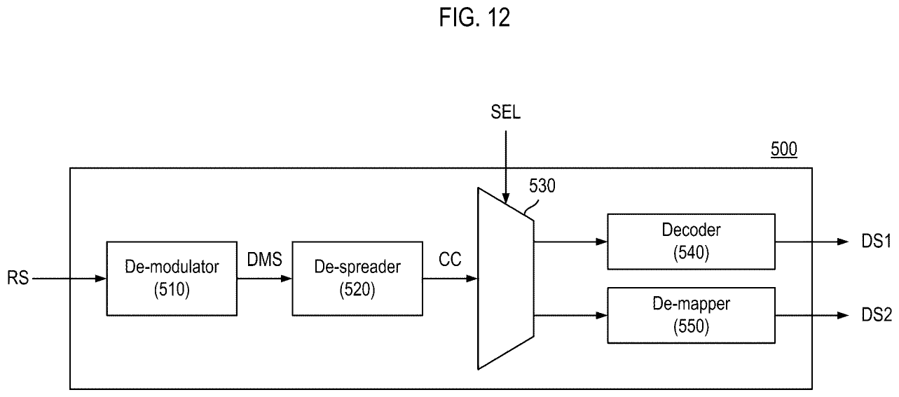

FIG. 12 is a block diagram of a receiver according to one or more example embodiments.

Referring to FIG. 12, a receiver 500 according to one or more example embodiments may include a demodulator 510, a despreader 520, a multiplexer 530, a decoder 540, and a demapper 550.

The demodulator 510 may demodulate a receive signal RS and output a demodulated signal. According to one or more example embodiments, the demodulator 510 may be configured to perform at least one of an operation of obtaining an in-phase (I) component and a quadrature (Q) component from the receive signal RS, an operation of removing a high-frequency component of the receive signal RS, an operation of conversion into a digital domain through sampling, and an operation of mapping the I component and the Q component to a bit signal.

According to one or more example embodiments, when the receive signal RS is a signal modulated by O-QPSK at a transmitter, the demodulator 510 may additionally perform an operation to compensate for a delay of the Q component. This takes a characteristic of O-QPSK, in which the Q component is delayed by ½ symbol (for example, 1 bit), into consideration, unlike QPSK.

The despreader 520 may despread the demodulated signal provided from the demodulator 510 and output a plurality of correlation values. The plurality of correlation values may be defined in a single symbol unit.

The multiplexer 530 may be configured to transmit a correlation value to the decoder 540 based on forward error correction (FEC) being applied to the receive signal RS and to transmit the correlation value to the demapper 550 based on the FEC being not applied to the receive signal RS. For example, the multiplexer 530 may transmit the correlation value to the decoder 540 or the demapper 550 depending on whether the FEC is applied to the receive signal RS.

According to one or more example embodiments, the application of the FEC may be defined through a selection signal SEL. For example, the selection signal SEL may include a 1-bit signal indicating whether the FEC is applied. The multiplexer 530 may transmit the correlation value to the decoder 540 when the selection signal SEL indicates a first logic (indicating that the first logic indicates that the FEC is applied to the receive signal RS). Alternatively, the multiplexer 530 may transmit the correlation value to the demapper 550 when the selection signal SEL indicates a second logic (indicating that the second logic indicates that the FEC is not applied to the receive signal RS).

When the FEC is applied, the receive signal RS may be encoded such that an error correction code for error detection and correction is added at a transmitter side. For example, the receive signal RS may be encoded from the transmitter through a binary convolutional code according to the above-described one or more embodiments, where the FEC is applied to the receive signal RS.

When the FEC is applied through the binary convolutional code, decoding through the Viterbi decoder 540 is required. Therefore, the correlation value may be transmitted to the decoder 540.

Example embodiments are not limited to an example of selective transmission of a correlation value through the above-described multiplexer 530. For example, the multiplexer 530 may be replaced with other elements that may selectively transmit the correlation value to the decoder 540 or the demapper 550.

For example, the receiver 500 may include a selection circuit, not illustrated, which may determine whether the FEC is applied or receive a signal indicating whether the FEC is applied, and a selection circuit, not illustrated, may selectively transmit the correlation value to the decoder 540 or the demapper 550 depending on whether the FEC is applied.

The decoder 540 may regard the correlation value as a branch metric according to the above-described one or more embodiments, and output a first decoding signal DS1 through decoding based on the correlation value.

The demapper 550 may be configured to calculate an LLR for a symbol included in the demodulated signal based on the correlation value and to convert the symbol into a bit sequence based on the LLR. The demapper 550 may output the converted bit sequence as a second decoded signal DS2. When the FEC is not applied, decoding based on the LLR may also restore the original signal.

According to one or more example embodiments, the receiver 500 and/or the multiplexer 530 may determine whether the FEC is applied according to the configurations in the following Table 1.

TABLE 1

| | Data Rate | | |
|---|---|---|---|
| Config # | (kb/s) | FEC in PHR | FEC in Payload |
| 1 | 250 | N | N |
| 2 | 500 | Y | Y |
| 3 | 1000 | Y | N |
| 4 | 250 | Y | Y |
| 5 | 1000 | Y | Y |
| 6 | 250 | N | N |
| 7 | 250 | Y | Y |

| | | |
|---|---|---|
| 8 | varies | Uses SFD signaling |

Referring to Table 1, a data rate, whether the FEC is applied to a physical header, and whether the FEC is applied to a payload may be defined based on configurations Config #. When the FEC is applied to at least one of the physical header or the payload, the multiplexer 530 may transmit the correlation value to the decoder 540. For example, in the configuration 3, the data rate may be defined as 1000 kb/s, and the FEC is applied to the physical header, such that the multiplexer 530 may transmit the correlation value to the decoder 540.

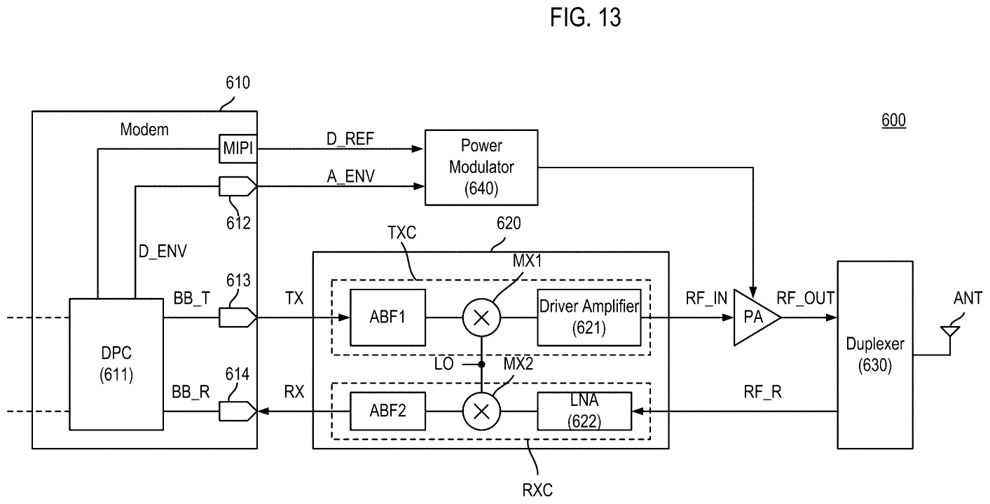

FIG. 13 is a diagram illustrating a wireless communication device according to one or more example embodiments.

Referring to FIG. 13, a wireless communication device 600 may include a modem 610, a radio-frequency integrated circuit (RFIC) 620, a power amplifier PA, a duplexer 630, a power modulator 640, and an antenna ANT.

The modem 610 may include a digital processing circuit 611, a first digital-to-analog Converter (DAC) 612, a second DAC 613, an analog-to-digital converter (ADC) 614, and a mobile industry processor interface (MIPI). The modem 610 may process a baseband signal BB_T (for example, including an I signal and a Q signal) including information to be transmitted through the digital processing circuit 611 according to various communication schemes. The modem 610 may process a received baseband signal BB_R through the digital processing circuit 611 according to various communication schemes.

For example, the modem 610 may process a signal to be transmitted or a received signal according to a communication scheme such, for example but not limited to, as orthogonal frequency division multiplexing (OFDM), orthogonal frequency division multiple access (OFDMA), wideband code multiple access (WCDMA), or high speed packet access+ (HSPA+). In addition, the modem 610 may process the baseband signal BB_T or the baseband signal BB_R according to various types of communication schemes (for example, various communication schemes to which a technique for modulating or demodulating an amplitude and/or a frequency of the baseband signal BB_T or BB_R is applied).

The modem 610 may extract an envelope of the baseband signal BB_T through the digital transmission processor 611 and generate a digital envelope signal D_ENV based on the extracted envelope.

According to one or more example embodiments, the modem 610 may generate an average power signal D_REF based on an average power tracking (APT) table stored in a memory. The APT table may store information on a required power supply voltage of the power amplifier PA based on expected output power (or transmission power) of the antenna ANT, and information on an average power signal D_REF corresponding to the required power supply voltage of the power amplifier PA may be stored in the APT table. Accordingly, when the expected output power of the antenna ANT is determined, the modem 610 may generate an average power signal D_REF using the APT table and provide the generated average power signal D_REF as a reference voltage signal to the power modulator 640.

The digital processing circuit 611 may perform various processing operations on a baseband signal in a digital domain.

For example, the digital processing circuit 611 may perform the above-described average power signal generation, envelope extraction, digital envelope signal generation, crest factor reduction (CFR), shaping function (SF), digital pre-distortion (DPD), delay compensation operations, or the like.

The CFR may reduce a peak-to-average power ratio (PAPR) of the communication signal (for example, the baseband signal BB_T). The SF may modify a digital envelope signal D_ENV to improve an efficiency and linearity of the power amplifier PA. The DPD may compensate for distortion of the power amplifier PA in the digital domain and linearize the compensated distortion. The delay compensation operation may compensate for a delay of the digital envelope signal D_ENV or the baseband signal BB_T.

The digital processing circuit 611 may output the digital envelope signal D_ENV and the baseband signal BB_T. The digital envelope signal D_ENV may be converted into an analog envelope signal A_ENV through the first DAC 612 and provided to the power modulator 640, and the baseband signal BB_T may be converted into a transmission signal TX through the second DAC 613 and provided to a transmission circuit TXC.

Although not illustrated in the drawing, the digital processing circuit 611 may include additional internal components for processing the above-described operations (for example, baseband signal processing, envelope extraction, digital envelope signal generation, or the like).

According to the above-described one or more embodiments, the digital processing circuit 611 may be configured to demodulate and decode a receive signal RX and the baseband signal BB_R. For example, the digital processing circuit 611 may demodulate the received signal and despread the demodulated signal based on a reference chip sequence. The digital processing circuit 611 may regard a correlation value corresponding to the despreading as a branch metric between states and determine a survivor path using the correlation value. The digital processing circuit 611 may output the decoded signal by tracing back the determined survivor path.

Each of the second DAC 613 and the ADC 614 may be provided in singular or plural. The modem 610 may convert the baseband signal BB_T into an analog signal using the second DAC 613 to generate a transmission signal TX. The modem 610 may receive the receive signal RX, an analog signal, from the RFIC 620. The modem 610 may extract the baseband signal BB_R, a digital signal, by digitally converting the received signal RX through the ADC 614 provided therein. For example, the receive signal RX may be a differential signal including a positive signal and a negative signal.

The RFIC 620 may generate an RF input signal RF_IN by performing up-conversion on the transmission signal TX or generate the receive signal RX by performing down-conversion on an RF received signal RF_R. For example, the RFIC 620 may include a transmit circuit TXC for up-conversion, a receive circuit RXC for down-conversion, and a local oscillator LO.

The transmit circuit TXC may include a first analog baseband filter ABF1, a first mixer MX1, and a driver amplifier 621. For example, the first analog baseband filter ABF1 may include a low pass filter.

The baseband filter ABF1 may filter the transmit signal TX received from the modem 610 and provide the filtered transmit signal TX to the first mixer MX1. For example, the baseband filter ABF1 may filter the baseband signal. The first mixer MX1 may perform up-conversion to convert a frequency of the transmit signal TX from a baseband to a high-frequency band through a frequency signal provided by the local oscillator LO. Through such up-conversion, the transmit signal TX may be provided to the driver amplifier 621 as the RF input signal RF_IN and the driver amplifier 621 may amplify the RF input signal RF_IN firstly in power and provide the firstly amplified input signal RF_IN to the power amplifier PA.

The power amplifier PA may receive a DC voltage or a variable power supply voltage (for example, a dynamically variable output voltage) and may amplify the power of the RF input signal RF_IN secondly based on the supplied power supply voltage to generate an RF output signal RF_OUT. The power amplifier PA may provide the generated RF output signal RF_OUT to the duplexer 630.

The receive circuit RXC may include a second analog baseband filter ABF2, a second mixer MX2, and a low-noise amplifier (LNA) 622. For example, the second analog baseband filter ABF2 may include a low pass filter.

The LNA 622 may amplify the RF receive signal RF_R provided from the duplexer 630 and provide the amplified RF receive signal RF_R to the second mixer MX2. The second mixer MX2 may perform down-conversion to convert a frequency of the receive signal RF_R from a high-frequency band to a baseband band through the frequency signal provided by the local oscillator LO. For example, the second mixer MX2 may convert the RF receive signal RF_R into a baseband signal using the LO signal.

Through such down-conversion, the RF receive signal RF_R corresponding to the baseband signal may be provided to the second analog baseband filter ABF2 as the receive signal RX and the second analog baseband filter ABF2 may filter the receive signal RX corresponding to the baseband signal and provide the filtered receive signal RX to the modem 610.

For reference, the wireless communication device 600 may transmit a transmit signal through a plurality of frequency bands using carrier aggregation (CA). To this end, the wireless communication device 600 may include a plurality of power amplifiers PAs that amplify a plurality of RF input signals RF_IN, respectively corresponding to a plurality of carriers. For ease of description, an example will be provided in which a single power amplifier PA is provided.

The duplexer 630 may be connected to the antenna ANT to separate a transmit frequency and a receive frequency. Specifically, the duplexer 630 may separate the RF output signal RF_OUT, provided from the power amplifier PA, for each frequency band and provide the separated RF output signal RF_OUT to the corresponding antenna ANT. Also, the duplexer 630 may provide an external signal, provided from the antenna ANT, to the LNA 622 included in the receive circuit RXC of the RFIC 620. For example, the duplexer 630 may include a front end module with integrated duplexer (FEMiD).

For reference, the wireless communication device 600 may be provided with a switch structure, which is capable of separating the transmit frequency and the receive frequency, instead of the duplexer 630. Also, the wireless communication device 600 may be provided with a structure including a duplexer 630 and a switch to separate the transmit frequency and the receive frequency. For ease of description, an example will be provided in which the wireless communication device 600 is provided with a duplexer 630 which is capable of separating the transmit frequency and the receive frequency.

The power modulator 640 may generate a modulated output voltage having a dynamically varying level based on the analog envelope signal A_ENV and the average power signal D_REF, and may provide an output voltage as a supply voltage to the power amplifier PA.

For example, the power modulator 640 may receive an average power signal D_REF and an analog envelope signal A_ENV from the modem 610. The power modulator 640 may generate a dynamically variable output voltage by operating in either an envelope tracking (ET) mode or an APT mode based on the received average power signal D_REF and analog envelope signal A_ENV. The power modulator 640 may supply the generated output voltage as a power supply voltage to the power amplifier PA.

For reference, when a fixed level of power supply voltage is applied to the power amplifier PA, a power efficiency of the power amplifier PA may be reduced. Accordingly, to efficiently manage the power of the power amplifier PA, the power modulator 640 may modulate an input voltage (for example, power supplied from a battery) based on at least one of the analog envelope signal A_ENV and the average power signal D_REF and provide the modulated voltage as a power supply voltage to the power amplifier PA.

The antenna ANT may transmit the RF output signal RF_OUT, which is frequency-separated by the duplexer 630, to an outside or provide the RF receive signal RF_R, received from the outside, to the duplexer 630. For example, the antenna ANT may include an array antenna, but example embodiments are not limited thereto.

For reference, the modem 610, the RFIC 620, the power amplifier PA, the duplexer 630, and the power modulator 640 may each be individually implemented as an integrated circuit (IC), a chip, and/or a module. Also, the modem 610, the RFIC 620, the power amplifier PA, the duplexer 630, and the power modulator 640 may be mounted together on a printed circuit board (PCB). However, example embodiments are not limited thereto. In some embodiments, at least a portion of the modem 610, the RFIC 620, the power amplifier PA, the duplexer 630, and the power modulator 640 may be implemented as a single communication chip.

Furthermore, the wireless communication apparatus 600 illustrated in FIG. 13 may be included in a wireless communication system using a cellular network such as 5th generation (5G) or long term evolution (LTE), or may be included in a wireless local area network (WLAN) system or any other wireless communication system. For reference, the configuration of the wireless communication device 600 illustrated in FIG. 13 is provided only as an example. Therefore, example embodiments are not limited thereto, and the wireless communication device 600 may be configured in various ways depending on the communication protocol or communication scheme.

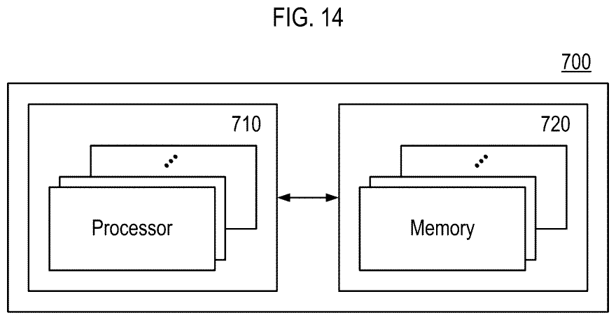

FIG. 14 is a block diagram of an electronic device according to one or more example embodiments.

Referring to FIG. 14, an electronic device 700 according to one or more example embodiments may include one or more processors (or processing circuits) 710 and one or more memories 720.

The one or more processors 710 may be electrically connected to the one or more memories 720 to control the one or more memories 720 and may be configured to execute at least one instruction stored in the one or more memories 720 to implement the descriptions, functions, procedures, proposals, methods, and/or operational flowcharts of the present application. Also, the one or more processors 710 may provide various operations according to various embodiments based on the instructions stored in the one or more memories 720. Also, the one or more processors 710 may process information stored in the one or more memories 720 to generate data.

According to one or more example embodiments, each of the one or more processors 710 may be an additional processor or a core included in a multi-core processor. A multi-core processor may be a single computing component having two or more independent processors, and each processor (or core) may read and execute instructions.

In one or more example embodiments, the one or more processors 710 may include one or more processing elements that may be symmetric or asymmetric. A processing element may refer to hardware or logic for supporting a software thread. For example, a hardware processing element may include a thread unit, a thread slot, a thread, a process unit, a context, a context unit, a logical processor, a hardware thread, and a core. For example, a processing element may refer to any hardware that may be independently associated with software threads, operating systems, applications, or other code.

In one or more example embodiments, the one or more processors 710 may be implemented as a general-purpose processor, a specific-purpose processor, or an application processor AP. For example, the one or more processors 710 may be implemented as a computing processor (for example, a central processing unit (CPU), a graphics processing unit (GPU), or the like) including a specific-purpose logic circuit (for example, a field programmable gate array (FPGA), application specific integrated circuits (ASICs), or the like).

The one or more memories 720 may be electrically connected to the one or more processors 710 and may store various information related to the operation of the one or more processors 710. For example, the one or more memories 720 may store software code including at least one instruction for performing a portion or all of the processes or threads controlled by the one or more processors 710 or for performing the descriptions, functions, procedures, proposals, methods, and/or operational flowcharts of the present application. For example, the software code may be implemented in a procedural or object-oriented programming language, or may be implemented in assembly language or machine language, as necessary. Alternatively, the software code may be implemented in a declarative programming language. Also, example embodiments are not limited to an arbitrary specific programming language.

The one or more processors 710 may execute at least one instruction stored in the one or more memories 720 to perform the operations and functions according to the above-described one or more embodiments of FIGS. 1 to 13.

At least one of the components, elements, modules or units (collectively “components” in this paragraph) represented by a block in the drawings, may be embodied as various numbers of hardware, software and/or firmware structures that execute respective functions described above, according to an example embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above example embodiments may be implemented in algorithms that execute on one or more processors. Furthermore, the components represented by a block or processing steps may employ any number of related art techniques for electronics configuration, signal processing and/or control, data processing and the like.

According to one or more example embodiments, the one or more processors may execute at least one instruction to receive a correlation value corresponding to despreading of a demodulated signal, determine a survivor path for states based on the correlation value being used as a branch metric between states, and trace back the survivor path to output a decoding signal.

According to one or more example embodiments, the one or more processors may select as many correlation values as the number of branches that an arbitrary state may have from among a plurality of correlation values corresponding to bit combinations to select a correlation value regarded as a branch metric.

The electronic device 700 according to the above-described one or more embodiments may decode a receive signal without calculating the branch metric, such that a hardware area of elements for calculating the branch metric may be reduced and a delay caused by the elements may be removed.

As set forth above, according to one or more example embodiments, a decoder for efficient Viterbi decoding, an operation method, and an electronic device may be provided.

While example embodiments have been shown and described above, it will be apparent to those skilled in the art that modifications and variations could be made without departing from the scope of the present inventive concept as defined by the appended claims and their equivalents.

What is claimed is:

1. A receiver comprising hardware circuitry that implements:
a demodulator configured to demodulate a received signal;
a despreader configured to, based on a reference chip sequence, perform dispreading on a demodulation signal corresponding to the demodulation of the received signal; and
a decoder configured to determine a survivor path for states based on a correlation value corresponding to the despreading, while omitting calculation of a log-likelihood ratio (LLR) for a symbol included in the demodulation signal, and output a decoding signal by tracing back the survivor path.

2. The receiver of claim 1, wherein the received signal is an offset-quadrature phase shift keying (O-QPSK) modulated signal.

3. The receiver of claim 1, wherein the despreader is configured to perform the despreading through a correlation operation between the demodulation signal and the reference chip sequence.

4. The receiver of claim 1, wherein the correlation value is defined for each bit combination of the symbol.

5. The receiver of claim 4, wherein the decoder is configured to select a correlation value, of which a number is equal to a number of possible branches that an arbitrary state has, from among a plurality of correlation values respectively corresponding to bit combinations of the symbol.

6. The receiver of claim 5, wherein the correlation value, of which the number is equal to the number of possible branches, is defined as a branch metric for the arbitrary state.

7. The receiver of claim 1, wherein an arbitrary state, among the states, has four transitions at an arbitrary time.

8. The receiver of claim 1, wherein the decoder is configured to:
for an arbitrary state, update a path metric of a current state to a minimum value among a sum of path metrics of a plurality of previous states and branch metrics of a plurality of previous transitions to the arbitrary state; and
determine the survivor path based on a finally updated path metric indicating a minimum value among path metrics of the current state.

9. The receiver of claim 1, wherein the hardware circuitry further comprises:
a demapper configured to calculate the LLR based on the correlation value and convert the symbol into a bit sequence based on the LLR; and
a multiplexer configured to transmit the correlation value to the decoder based on forward error correction (FEC) being applied to the received signal, and transmit the correlation value to the demapper based on the FEC being not applied to the received signal.

10. A method of operating a decoder, the method comprising:
receiving a correlation value corresponding to despreading for a demodulation signal;
determining a survivor path for states based on the correlation value, while omitting calculation of a log-likelihood ratio (LLR) for a symbol included in the demodulation signal; and
outputting a decoding signal by tracing back the survivor path.

11. The method of claim 10, wherein the correlation value is defined for each bit combination of the symbol.

12. The method of claim 11, further comprising:
selecting a correlation value, of which a number is equal to a number of possible branches that an arbitrary state has, from among a plurality of correlation values respectively corresponding to bit combinations of the symbol.

13. The method of claim 12, wherein the correlation value, of which the number is equal to the number of possible branches, is defined as a branch metric for the arbitrary state.

14. The method of claim 10, wherein an arbitrary state, among the states, has four transitions at an arbitrary time.

15. The method of claim 10, wherein the determining the survivor path comprises:
for an arbitrary state, updating a path metric of a current state to a minimum value among a sum of path metrics of a plurality of previous states and branch metrics of a plurality of previous transitions to the arbitrary state; and
determining the survivor path based on a finally updated path metric indicating a minimum value among path metrics of the current state.

16. An electronic device comprising:
at least one memory configured to store at least one instruction; and
at least one processor configured to execute the at least one instruction, wherein the at least one processor, by executing the at least one instruction, is configured to:
receive a correlation value corresponding to despreading for a demodulation signal;
determine a survivor path for states based on the correlation value, while omitting calculation of a log-likelihood ratio (LLR) for a symbol included in the demodulation signal; and
output a decoding signal by tracing back the survivor path.

17. The electronic device of claim 16, wherein the correlation value is defined for each bit combination of the symbol.

18. The electronic device of claim 17, wherein the at least one processor, by executing the at least one instruction, is configured to select a correlation value, of which a number is equal to a number of possible branches that an arbitrary state has, from among a plurality of correlation values respectively corresponding to bit combinations of the symbol.

19. The electronic device of claim 18, wherein the correlation value, of which the number is equal to the number of possible branches, is defined as a branch metric for the arbitrary state.

20. The electronic device of claim 16, wherein an arbitrary state, among the states, has four transitions at an arbitrary time.
